(19) United States
(12) Patent Application Publication
(10) Pub. No.: US 2008/0265917 A1
(43) Pub. Date: Oct. 30, 2008

(54) Return loss bridge circuit

(75) Inventors: Richard Schwarz, Northfield, OH (US); Leo Staschover, Fort Lauderdale, FL (US); Ron N. Sanelli, Maspeth, NY (US)

Correspondence Address: BODNER & O'ROURKE, LLP, 425 BROADHOLLOW ROAD, SUITE 108, MELVILLE, NY, 11747, US

(73) Assignee: Porta Systems Corporation, Syosset, NY (US)

(21) Appl. No.: 11/974,993

(22) Filed: Oct. 17, 2007

Related U.S. Application Data
(60) Provisional application No. 60/852,535, filed on Oct. 18, 2006.

(51) Int. Cl. G01R 17/00

(52) U.S. Cl. 324/725

(57) ABSTRACT

A return loss bridge circuit for testing a balanced test impedance includes an input connector and a reflection connector. The input connector and the reflection connector are electrically connected to an output of a network analyzer and an input of the network analyzer, respectively. The return loss bridge circuit further includes a reference impedance connected between the input and reflection connectors, first and second transformers and a common mode choke. The common mode choke is electrically connectable to the balanced test impedance.

### CROSS REFERENCE TO RELATED APPLICATION

This application is related to U.S. Provisional Application Ser. No. 60/852,535, filed on Oct. 18, 2006, and entitled “Return Loss Bridge Circuit”, the disclosure of which is incorporated herein by reference and on which priority is hereby claimed.

### BACKGROUND OF THE INVENTION

1. Field of the Invention

The present invention relates generally to circuits which measure the impedance mismatch between a signal transmission line and a signal source connected thereto, and more specifically relates to a return loss bridge circuit.

2. Description of the Prior Art

### Return Loss

“Return Loss” is a convenient way to express the magnitude of an impedance in relation to a reference impedance.

In communication circuits the object is to insure maximum power transfer from a generator to a load. This occurs when the load matches the internal impedance of the generator, i.e., Z=R_{S}. The degree of mismatch or power loss is then best described by relating load impedance Z to generator impedance R_{S}.

As shown in FIGS. 1A and 1B, for a one-port load circuit, one may represent load impedance Z by an equivalent circuit consisting of a generator Eᵣ in series with an impedance R_{S}′ equal to the internal impedance R_{S} of primary generator E₀. Generator Eᵣ creates “negative” or “reflected” power that subtracts from the “incident” power supplied by primary generator E₀, thereby reducing the power delivered to the load. The “negative” power is zero when the circuit is matched, and rises with increasing mismatch. The ratio of the generator output voltages, Eᵣ/E₀, is known as the “reflection factor”, ρ, and, when expressed in dB, as the “return loss,” i.e., Return Loss=−20 log|ρ|.

### Return Loss Measurement

One approach to measuring return loss is based on the familiar Wheatstone Bridge, shown in FIG. 2. There, impedance is measured by adjusting the upper right-hand arm 2 of known impedances to produce a null in the detector circuit 4. If that arm 2 is set to the reference value, R_{S}, the magnitude of the unbalance voltage measured by the detector 4 will be proportional to the reflection factor.

### Return Loss Bridges

In the schematic of FIG. 3, the two left arms of the Wheatstone bridge have been replaced by an autotransformer 6 which makes it possible to ground one side of the detector circuit 4 as well as the signal source 12 (i.e., generator E with an internal resistance 14). With a 100 ohm resistor 8 in the reference arm 10, the circuit then becomes a 100 ohm coax return loss bridge when operated from a 50 ohm source 12.

Many return loss bridges are designed for use with 50 and 75 ohm network analyzers.

The procedure is to set the network analyzer display to 0 dB when the bridge test port 16 is either unterminated or shorted, i.e., when there occurs 100% reflection. The display will then read return loss directly.

There are many bridge circuits covering a variety of frequency ranges for 50 ohm, 75 ohm and a variety of balanced impedances. The 100 ohm balanced return loss bridge of FIG. 3 is most convenient for making return loss measurements of UTP cables on a 50 ohm network analyzer.

There is also a need for return loss bridges to measure 75 ohm circuits on a 50 ohm network analyzer directly without any correction factors.

### OBJECTS AND SUMMARY OF THE INVENTION

It is an object of the present invention to provide a return loss bridge circuit for testing a balanced test impedance.

It is another object of the present invention to provide a return loss bridge circuit that measures 75 ohm circuits on a 50 ohm network analyzer directly without any correction factors.

It is a further object of the present invention to provide a return loss bridge circuit which minimizes or eliminates the common mode voltage caused by a mismatched test load which may have otherwise affected the accuracy of the return loss measurement.

It is yet another object of the present invention to provide a return loss bridge circuit that is suitable for testing coaxial cables.

It is still a further object of the present invention to provide a return loss bridge circuit which is particularly suitable for making accurate return loss measurements of balanced loads with grounded center taps.

In accordance with the present invention, a return loss bridge circuit for testing a balanced test impedance, where the balanced test impedance includes a first electrical end and a second electrical end, includes an input connector and a reflection connector. The input connector and the reflection connector are electrically connected to an output of a network analyzer and an input of the network analyzer, respectively. The return loss bridge circuit further includes a reference impedance connected between the input and reflection connectors, first and second transformers and a common mode choke. Each of the first and second transformers has a first winding and a second winding, each of the windings having a first electrical end and a second electrical end. Also, the common mode choke has a first winding and a second winding, each of which includes a first electrical end and a second electrical end.

The first electrical end of the first winding of the first transformer is electrically connected to the input connector and to the reference impedance. The second electrical end of the first winding of the first transformer is electrically connected to the second electrical end of the second winding of the second transformer. The first electrical end of the second winding of the first transformer is electrically connected to the first electrical end of the second winding of the second transformer and to ground. The second electrical end of the second winding of the first transformer is electrically connected to the first electrical end of the first winding of the common mode choke.

The first electrical end of the first winding of the second transformer is electrically connected to the reflection connector and to the reference impedance. The second electrical end of the first winding of the second transformer is electrically connected to the first electrical end of the second winding of the common mode choke.

The second electrical ends of the first and second windings of the common mode choke are electrically connectable to first and second electrical ends of the balanced test impedance.

These and other objects, features and advantages of the present invention will be apparent from the following detailed description of illustrative embodiments thereof, which is to be read in connection with the accompanying drawings.

### BRIEF DESCRIPTION OF THE DRAWINGS

FIG. 1A is a schematic diagram of a conventional single loop circuit illustrating a generating signal source and a load connected thereto.

FIG. 1B is a schematic diagram of the equivalent circuit of that shown in FIG. 1.

FIG. 2 is a schematic diagram of a conventional circuit for measuring return loss.

FIG. 3 is a schematic diagram of an alternative conventional circuit for measuring return loss.

FIG. 4 is a schematic diagram of a 100 ohm return loss bridge circuit constructed in accordance with a first form of the present invention.

FIGS. 5A, 5B and 5C are schematic diagrams of equivalent circuits of that shown in FIG. 4.

FIG. 6 is a schematic diagram of a return loss bridge constructed in accordance with a second form of the present invention.

FIG. 7 is a schematic diagram of a return loss bridge constructed in accordance with a third form of the present invention.

FIG. 8 is a schematic diagram of a return loss bridge constructed in accordance with a fourth form of the present invention.

FIG. 9 is a schematic diagram of a return loss bridge constructed in accordance with a fifth form of the present invention.

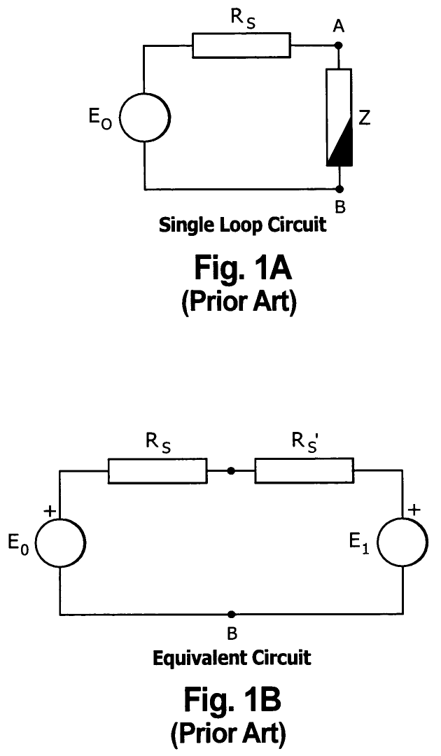

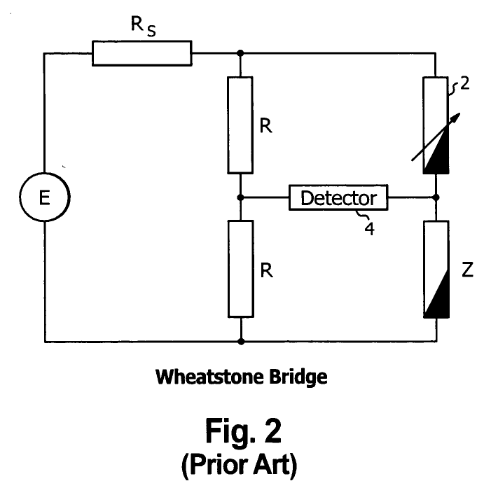

### DETAILED DESCRIPTION OF THE PREFERRED EMBODIMENTS

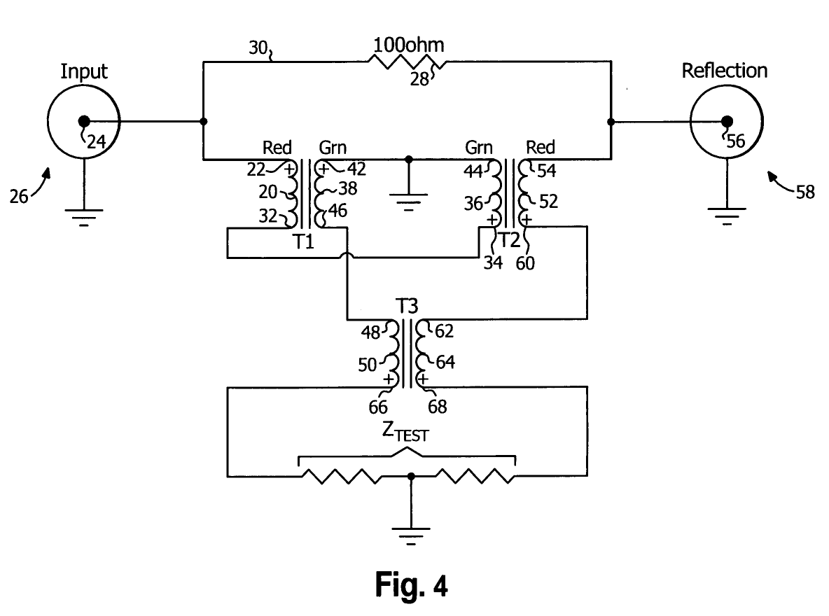

A schematic of a balanced return loss bridge constructed in accordance with a first form of the present invention is shown in FIG. 4. In this circuit, transformers T1 and T2 have a common core, and transmission line transformer T3 acts as a separate common mode choke.

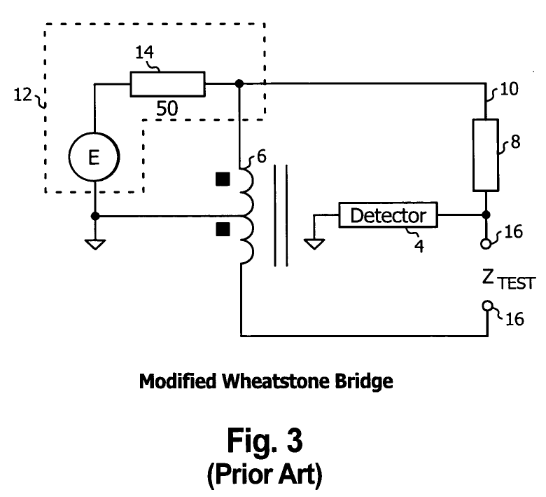

By splitting the lower half of the autotransformer 6 in the circuit of FIG. 3 into equal halves (i.e., transformers T1 and T2) and inserting the test impedance Z_{TEST} between the two half windings, the return loss bridge is converted from 100 ohm coax to 100 ohm balanced. The presence of common mode choke T3 makes it possible to accommodate balanced test impedances with the center grounded.

More specifically, the first winding 20 of transformer T1 has a first electrical end 22 electrically coupled to the center (signal) conductor 24 of the input connector 26 and to one electrical end of a reference impedance 28 (in this example, a 100 ohm resistor) situated in the reference leg 30 of the circuit. The other opposite second electrical end 32 of the first winding 20 of transformer T1 is electrically coupled to a second electrical end 34 of the second winding 36 of transformer T2. The second winding 38 of transformer T1 has a first electrical end 42 electrically coupled to the opposite first electrical end 44 of the second winding 38 of transformer T2 and to ground, and has a second electrical end 46 electrically coupled to the first electrical end 48 of the first winding 50 of the common mode choke T3.

The first winding 52 of transformer T2 has its first electrical end 54 electrically coupled to the center (signal) conductor 56 of the reflection connector 58 and to the other opposite electrical end of the reference impedance 28. The opposite second electrical end 60 of the first winding 52 of transformer T2 is electrically coupled to the first electrical end 62 of the second winding 64 of the common mode choke T3.

The second electrical end 66 of the first winding 50 of choke T3 and the second electrical end 68 of the second winding 64 of choke T3 are electrically coupled to opposite electrical ends of the balanced impedance under test, Z_{TEST}. The instantaneous polarity in the transformers T1 and T2 and common mode choke T3, resulting from the particular direction in which the windings are wound, is denoted by the “plus” (+) sign at ends 22 of transformer T1, ends 34 and 60 of transformer T2, and ends 66 and 68 of choke T3. The first and second windings 20, 38 of transformer T1 are preferably wound in the same direction, as are the first and second windings 52, 38 of transformer T2. First and second windings 50, 64 of choke T3 are also preferably wound on the core of choke T3 in the same direction. Preferably, first ends 22 and 42 of transformer T1, second ends 34, 60 of transformer T2 and second ends 66, 68 of common mode choke T3 are of the same instantaneous polarity.

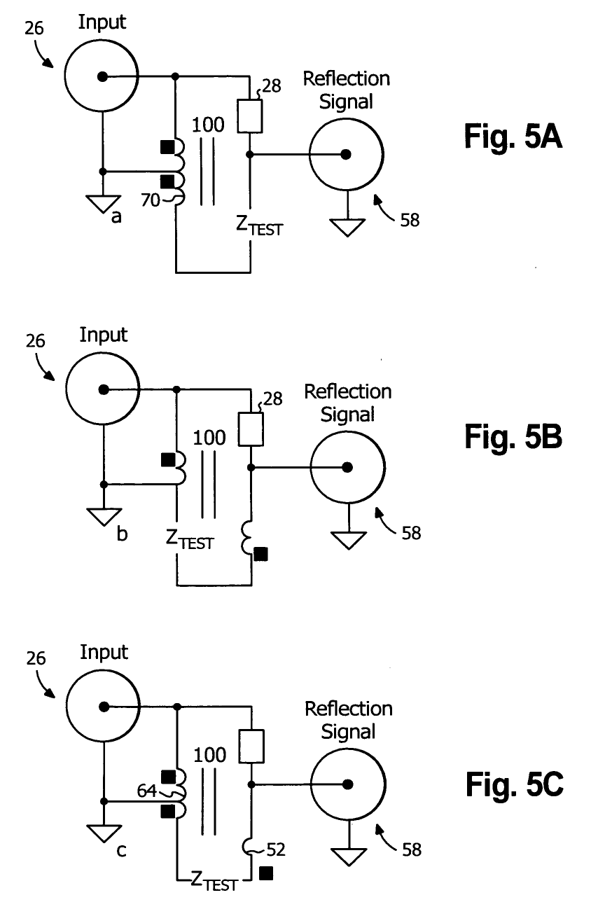

To understand the operation of the 100 ohm balanced return loss bridge shown in FIG. 4, the schematic of the circuit has been redrawn in different forms in FIG. 5. The equivalent circuit, without the common mode choke T3, shown in FIG. 5C, initially may not be very helpful unless one notes that the lower part of the circuit (when viewing FIG. 5C) between the reflected signal connector 58 and ground consists of two transformer windings 52, 64 and the test load Z_{TEST} in series. These three elements 52, 64, Z_{TEST} may be arranged in any arbitrary order without affecting the magnitude of the reflected signal. When one interchanges the positions of the test load Z_{TEST} and the right hand transformer winding 64 and combine the two transformer windings 52, 64 into a single one 70, one winds up with the circuit of FIG. 5A. It should be noted that the circuit of FIG. 5A is identical to that of FIG. 3 with the reflected signal representing the output of the detector 4.

All three circuits shown in FIGS. 5A, 5B and 5C will work with test impedances that are floating. However, none will give correct readings when the center point of a balanced impedance is grounded.

The reason is common mode which will be different for the three circuit versions shown in FIGS. 5A, 5B and 5C.

For a test load of 100 ohms, the common mode voltage in the equivalent circuits shown in FIGS. 5A and 5B will be ½ (one-half) the input voltage on the input connector 26. In the circuit shown in FIG. 5C, it will be zero. For mismatched loads, the common mode voltage in the circuit of FIG. 5C will be ½ (one-half) the reflected voltage, which is very much lower than that for the circuits of FIGS. 5A and 5B of the order of ½ (one-half) the input, depending on the magnitude of the load.

Clearly, the circuit of FIG. 5C is much preferred for the measurement of midpoint-grounded balanced loads, but requires a common mode choke T3 to get rid of whatever common mode voltage does exist.

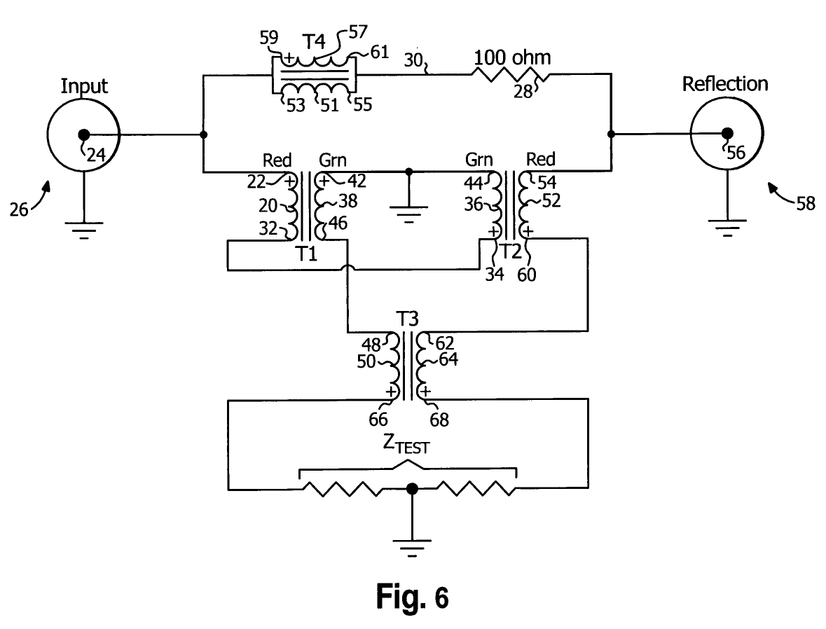

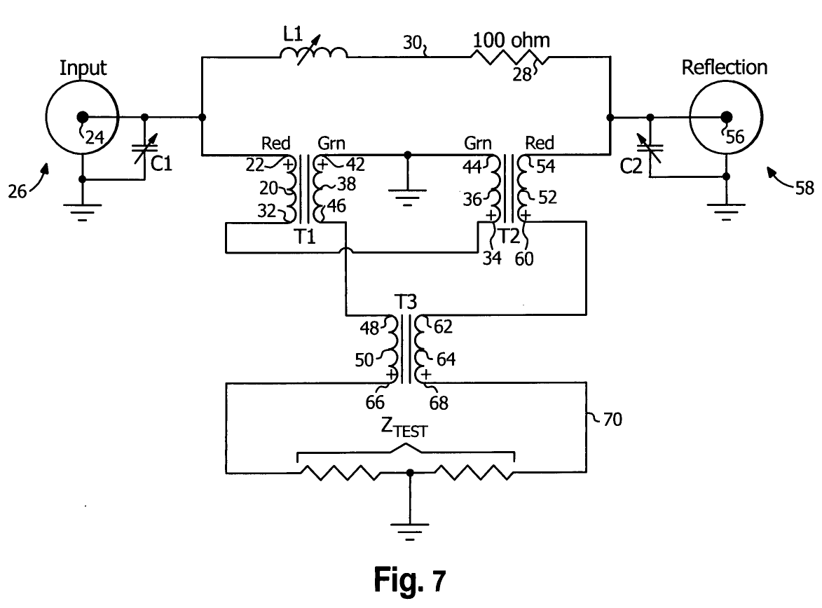

Although the balanced return loss bridge of the present invention shown in FIG. 4 is suitable for many applications, the circuits shown in FIGS. 6 and 7 are preferred. Since the common mode choke T3 in the circuit of FIG. 4 does have some impedance in the balanced mode, it will cause an error, however small, in the return loss reading.

The balanced, 50 to 100 ohm load, return loss bridge circuit of the present invention shown in FIG. 6 of the drawings makes possible a further improvement of performance.

It will be noted that the circuit of FIG. 6 is similar to the return loss bridge shown in FIG. 4, with like reference numbers indicating like components, except that a common mode choke T4 is added in the reference leg 30 of the return loss bridge, that is, in series with the internal reference resistor 28 (in this example, the 100 ohm resistor). Common mode choke T4 will balance out the small impedance effect of common mode choke T3 on the return loss measurement.

Common mode choke T4 includes a first winding 51 having a first electrical end 53 and a second electrical end 55, and a second winding 57 having a first electrical end 59 and a second electrical end 61. The first ends 53, 59 of the first and second windings 51, 57 are electrically connected together and to the signal conductor 24 of input connector 26. The second ends 55, 61 of the first and second windings 51, 57 are electrically connected together and to one electrical end of the reference impedance 28, as shown in FIG. 6. However, it should be realized that since choke T4 and reference impedance 28 are in series, their positions in the reference leg 30 of the circuit may be reversed, such that winding ends 55, 61 are electrically connected to signal conductor 56 of reflectance connector 58, and winding ends 53, 59 are electrically connected to one end of reference impedance 28 with the other end of reference impedance 28 being electrically connected to the signal conductor 24 of input connector 26.

Since it is well know that common mode chokes have frequency limitations, chokes T3 and T4 should be closely matched. As such, a preferred circuit for a return loss bridge, especially one for use with balanced loads, is shown in FIG. 7 of the drawings. This circuit not only balances out the effects of the common mode choke T3 in the measuring arm 70, but also tunes out stray impedances of the other transformers T1 and T2.

The return loss bridge of the present invention and shown in FIG. 7 is, again, similar in many respects to the return loss bridge shown in FIG. 4, with like reference numbers indicating like components, except that a variable inductor L1 (preferably an air core inductor) is added to the reference leg 30 of the circuit in series with the internal reference resistor 28 (shown by way of example in FIG. 7 as a 100 ohm resistor), rather than common mode choke T4 of the return loss bridge shown in FIG. 6 and described previously. Furthermore, variable trimmer capacitors C1 and C2 are placed respectively between the signal center conductors 24, 56 of the input and reflection connectors 26, 58 of the return loss bridge circuit and ground. The circuit of the return loss bridge shown in FIG. 7 and which is described below is preferably used for 50 to 100 ohm balanced loads and for two frequency ranges, 100 MHz and 300 MHz, but it should be understood that the general concept of the circuit can be applied for measuring return loss at lower and higher frequency ranges, as well.

Preferably, transformers T1, T2 and T3 (which acts as a common mode choke) in the return loss bridge circuits of the present invention shown in FIGS. 4, 6 and 7 are all wound using 2×28 bifilar Teflon wire. On the 100 MHz unit, transformers T1, T2 and T3 have 3 turns each. On the 300 MHz unit, transformers T1, T2 and T3 have 2 turns each. Transformers T1 and T2 are wound on the same toroid core and hooked up in a manner similar to a 4:1 Guanella transmission line transformer. Transformer T3, a 1:1 transmission line transformer, is wound on its own separate toroid core.

Both the input connector 26 and the reflection connector 58 are preferably coupled to a network analyzer (not shown). In the circuit of FIG. 7, capacitors C1 and C2 are provided for optimizing the circuit by tuning out stray capacitance or inductance in order to improve the accuracy of the measurement, and are adjusted by the manufacturer. The variable air core inductor L1 in the reference leg 30 of the circuit is used to offset the parasitics of transformers T1 and T2 as well as balance the characteristics of common mode choke T3.

The reference leg common mode choke T4 of the second embodiment of the return loss bridge shown in FIG. 6 is designed to match common mode choke T3 of the test leg 70, but does not totally cancel or balance out the leakage inductance or stray inductance (i.e., the residual inductance) from transformers T1 and T2. However, in the return loss bridge of the present invention shown in FIG. 7, the variable air core inductor L1 provides a more effective cancellation of the leakage and stray inductances and results in actual return loss measurements that are close to theoretical measurements, and further improves the directivity of the return loss bridge, so that the result is a very low measurement value in dB (decibels) when the load and signal source are matched. Variable air core inductor L1 basically provides the leakage inductance that common mode choke T4 provides in the second embodiment of the return loss bridge shown in FIG. 6, but also some additional, variable inductance to balance out the leakage and stray inductance associated with transformers T1 and T2.

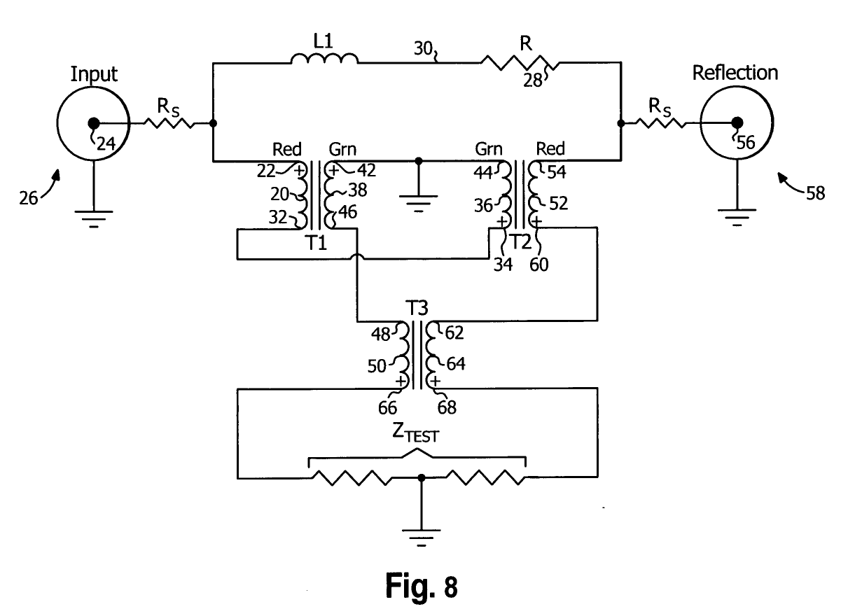

A further modified version of a balanced return loss bridge circuit formed in accordance with the present invention is shown in FIG. 8. This circuit is quite suitable for use in testing coaxial cables. It has been discovered that the reference impedance, R, could be changed from 50 ohms to 75 ohms and valid measurements of return loss made on a 50 ohm network analyzer without correction factors may be made by modifying the source and reflection load impedances.

Return loss bridge circuits formed in accordance with the present invention may include balanced impedances of 110, 120, 135 and 150 ohms in addition to the 100 ohm reference impedance, R, such as shown in FIG. 7. All such circuits would be identical except for the changed reference impedance, R, and the addition of two resistors, R_{S}, connected in series between the signal center conductor 24 of the input signal connector 26 and transformer T1, and in series between the signal center conductor 56 of the reflected signal connector 58 and transformer T2, as shown in FIG. 8. In FIG. 8, R represents the balanced impedance rating of the bridge. Again, reference numbers used in FIG. 8 denote components which are the same as or similar to those components of the circuit shown in FIG. 4 having the same reference numbers.

The value of resistors R_{S} in the return loss bridge circuit shown in FIG. 8 is R/2, which for a 100 ohm return loss bridge would be 50 ohms.

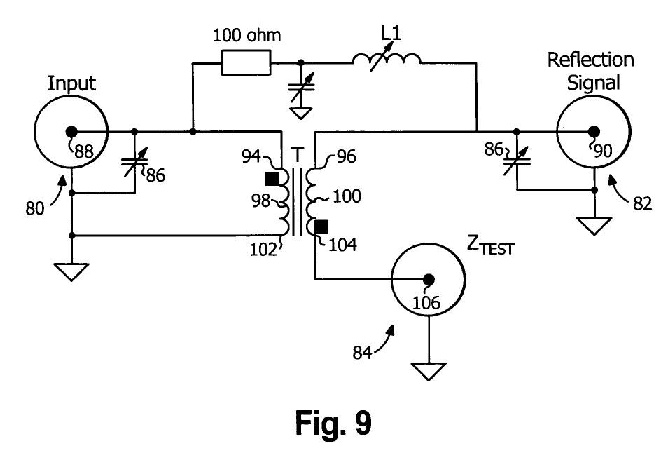

Another form of a return loss bridge circuit constructed in accordance with the present invention is shown in FIG. 9. Again, this return loss bridge circuit is particularly suitable for use in testing coaxial cables.

The return loss bridge circuit shown in FIG. 9 includes an input signal connector 80, a reflected signal connector 82 and a test impedance connector 84. Adjustable trimmer capacitors 86 are electrically connected between the signal center conductor 88 and ground on the input signal connector 80 and the signal center conductor 90 and ground on the reflected signal connector 82. A series circuit including a variable air core inductor L1 electrically coupled in series to the internal reference resistor 92 (in this example, the 100 ohm resistor shown in FIG. 9) is electrically coupled between the center conductors 88, 90 of the input signal connector 80 and the reflected signal connector 82. An adjustable, trimmer capacitor 94 is electrically connected between the juncture of the variable air-core inductor L1 and the reference resistor 92 and ground.

The center conductors 88, 90 of the input signal connector 80 and the reflected, signal connector 82 of the return loss bridge circuit of FIG. 9 are provided respectively to the first electrical ends 94, 96 of first and second windings 98, 100 of a transformer T, with the opposite second electrical end 102 of the first winding 98 being electrically connected to ground and the opposite second electrical end 104 of the second winding 100 being electrically connected to the signal center conductor 106 of the test impedance connector 84.

The windings 98, 100 of the transformer T are preferably wound in opposite directions on a toroid core using up to preferably 14 turns, depending on the frequency range. The wire used for the transformer T is preferably bifilar. The variable trimmer capacitors 86, 94 and variable air core inductor L1 are used to tune out stray inductance and capacitance.

The test procedure for measuring the return loss of a circuit or coaxial cable using the return loss bridge circuit of the present invention will now be described. First, the input connector 26, 80 of the return loss bridge of the present invention is connected directly to the network analyzer output. Second, the reflected signal “output” connector 58, 82 of the return loss bridge circuit is connected to the network analyzer input through a cable having an impedance equal to that of the network analyzer. Third, the display of the network analyzer is set to preferably 5 dB/div, with the zero line on top. With the test port 84 open, the network analyzer display is normalized to 0 dB. Fourth, the test port 84 is terminated with the test load and return loss is measured directly on the network analyzer.

The return loss bridge circuits of the present invention shown in FIGS. 4, 6, 7 and 8 and described previously are particularly suitable for making accurate return loss measurements of balanced loads with grounded center taps.

Although illustrative embodiments of the present invention have been described herein with reference to the accompanying drawing, it is to be understood that the invention is not limited to those precise embodiments, and that various other changes and modifications may be effected therein by one skilled in the art without departing from the scope or spirit of the invention.

What is claimed is:

1. A return loss bridge circuit for testing a balanced test impedance, the balanced test impedance having a first electrical end and a second electrical end, which comprises:
an input connector electrically connectable to an output of a network analyzer;
a reflection connector electrically connectable to an input of the network analyzer, each of the input connector and the reflection connector having a signal conductor;
a reference impedance having a first electrical end and a second electrical end, the first electrical end of the reference impedance being in electrical communication with the signal conductor of the input connector, the second electrical end of the reference impedance being in electrical communication with the signal conductor of the reflectance connector;
a first transformer and a second transformer, each of the first and second transformers having a first winding and a second winding, each of the first and second windings of the first and second transformers having a first electrical end and a second electrical end; and
a first common mode choke, the first common mode choke having a first winding and a second winding, each of the first and second windings of the first common mode choke having a first electrical end and a second electrical end, the first electrical end of the first winding of the first transformer being electrically connected to the signal conductor of the input connector and being in electrical communication with the first electrical end of the reference impedance, the second electrical end of the first winding of the first transformer being electrically connected to the second electrical end of the second winding of the second transformer, the first electrical end of the second winding of the first transformer being electrically connected to the first electrical end of the second winding of the second transformer and to ground, the second electrical end of the second winding of the first transformer being electrically connected to the first electrical end of the first winding of the first common mode choke, the first electrical end of the first winding of the second transformer being electrically connected to the signal conductor of the reflection connector and being in electrical communication with the second electrical end of the reference impedance, the second electrical end of the first winding of the second transformer being electrically connected to the first electrical end of the second winding of the first common mode choke, the second electrical end of the first winding of the first common mode choke being electrically connectable to the first electrical end of the balanced test impedance, the second electrical end of the second winding of the first common mode choke being electrically connectable to the second electrical end of the balanced test impedance.

2. A return loss bridge circuit as defined by claim 1, wherein the reference impedance is a resistor.

3. A return loss bridge circuit as defined by claim 1, which further comprises:
a second common mode choke, the second common mode choke being electrically connected in series with the reference impedance between the signal conductor of the input connector and the signal conductor of the reflection connector.

4. A return loss bridge circuit as defined by claim 3, wherein the first common mode choke and the second common mode choke have substantially the same characteristics.

5. A return loss bridge circuit as defined by claim 3, wherein the second common mode choke includes a first winding having a first electrical end and a second electrical end, and a second winding having a first electrical end and a second electrical end, the first electrical end of the first winding of the second common mode choke being electrically connected to the first electrical end of the second winding of the second common mode choke, the second electrical end of the first winding of the second common mode choke being electrically connected to the second electrical end of the second winding of the second common mode choke, the first electrical ends of the first and second windings of the second common mode choke being in electrical communication with one of the signal conductor of the input connector and the second electrical end of the reference impedance, and the second electrical ends of the first and second windings of the second common mode choke being in electrical communication with one of the first electrical end of the reference impedance and the signal conductor of the reflection connector.

6. A return loss bridge circuit as defined by claim 1, which further comprises:
an inductor, the inductor being electrically connected in series with the reference impedance between the signal conductor of the input connector and the signal conductor of the reflection connector.

7. A return loss bridge circuit as defined by claim 6, wherein the inductor is a variable inductor.

8. A return loss bridge circuit as defined by claim 6, which further comprises:
a first capacitor electrically connected between the signal conductor of the input connector and ground, and a second capacitor electrically connected between the signal conductor of the reflection connector and ground.

9. A return loss bridge circuit as defined by claim 6, which further comprises:
a first impedance electrically connected between the signal conductor of the input connector and the first electrical end of the first winding of the first transformer, and a second impedance electrically connected between the signal conductor of the reflection connector and the first electrical end of the first winding of the second transformer.

10. A return loss bridge circuit as defined by claim 9, wherein each of the first impedance and the second impedance is a resistor.

11. A return loss bridge circuit for testing a test impedance connectable thereto, which comprises:
an input connector electrically connectable to an output of a network analyzer;
a reflection connector electrically connectable to an input of the network analyzer;
a test impedance connector electrically connectable to the test impedance, each of the input connector, the reflectance connector and the test impedance connector having a signal conductor;
a reference impedance;
an inductor electrically connected in series with the reference impedance to at least partially define with the reference impedance a series reference leg circuit having a first electrical end and a second electrical end, the first electrical end of the series reference leg circuit being in electrical communication with the signal conductor of the input connector, the second electrical end of the series reference leg circuit being in electrical communication with, the signal conductor of the reflection connector; and
a transformer, the transformer having a first winding and a second winding, each of the first and second windings having a first electrical end and a second electrical end, the first electrical end of the first winding being electrically connected to the signal conductor of the input connector, the second electrical end of the first winding being electrically connected to ground, the first electrical end of the second winding being electrically connected to the signal conductor of the reflectance connector, the second electrical end of the second winding being electrically connected to the signal conductor of the test impedance connector.

12. A return loss bridge circuit as defined by claim 11, wherein the transformer includes a core, and wherein the first and second windings are wound in opposite directions on the core.

13. A return loss bridge circuit as defined by claim 11, wherein the inductor is a variable inductor.

14. A return loss bridge circuit as defined by claim 11, which further comprises:
a first capacitor and a second capacitor, the first capacitor being electrically connected between the signal conductor of the input connector and ground, the second capacitor being electrically connected between the signal conductor of the reflectance connector and ground.

15. A return loss bridge circuit as defined by claim 14, wherein the first and second capacitors are variable capacitors.

16. A return loss bridge circuit as defined by claim 11, which further comprises:
a capacitor, the capacitor being electrically connected between ground and the inductor and reference impedance of the series reference leg circuit.

17. A return loss bridge circuit as defined by claim 11, wherein the reference impedance is a resistor.
